(19) United States
(12) Patent Application Publication
(10) Pub. No.: US 2003/0235226 A1
(43) Pub. Date: Dec. 25, 2003

(54) Surface emitting semiconductor laser and method of fabricating the same

(75) Inventor: Nobuaki Ueki, Kanagawa (JP)

Correspondence Address: OLIFF & BERRIDGE, PLC, P.O. BOX 19928, ALEXANDRIA, VA, 22320, US

(73) Assignee: Fuji Xerox Co., Ltd., Tokyo (JP)

(21) Appl. No.: 10/375,133

(22) Filed: Feb. 28, 2003

(30) Foreign Application Priority Data
Jun. 20, 2002 (JP) 2002-180604

(51) Int. Cl. H01S 5/00

(52) U.S. Cl. 372/46

(57) ABSTRACT

A surface emitting semiconductor laser includes a substrate, a lower semiconductor multilayer mirror of a first conduction type formed on the substrate, an upper semiconductor multilayer mirror of a second conduction type, an active region disposed between the lower and upper semiconductor multilayer mirrors, a current confinement portion arranged between the lower and upper semiconductor multilayer mirrors, and a metal layer provided on the upper semiconductor multilayer mirror. A mesa structure is formed so as to include at least the upper semiconductor multilayer mirror, the current confinement portion and the metal layer. The mesa structure has a side surface aligned with the metal layer.

### BACKGROUND OF THE INVENTION

1. Field of the Invention

The present invention relates to a surface emitting semiconductor laser used as a source for optical information processing and optical communications and a method of fabricating such a laser. More particularly, the present invention relates to a surface emitting semiconductor layer having a stabilized lateral mode, a low threshold current and improved reliability and a method of fabricating the same.

2. Description of the Related Art

Recently, there has been an increased demand for a surface emitting semiconductor laser capable of easily realizing an array of sources in the technical fields of optical communications and optical interconnections. Hereinafter, the surface emitting semiconductor laser is defined so as to include both a surface emitting semiconductor laser itself and a device employing the laser. The multiplied sources enable parallel transmission (parallel processing) of data, so that the transmission capacity and rate can be drastically enhanced.

It is known that the surface emitting semiconductor laser has advantages of low threshold current and small power consumption, and on the other hand, has a small volume of the active region that is a gain medium (as small as 1/100 of that of the edge-emitting laser). Therefore, the surface emitting semiconductor laser has a difficulty in power up. In the surface emitting semiconductor laser, the optical power available from one spot has only a few milliwatts to ten milliwatts at most.

The surface emitting semiconductor laser is categorized into a proton injection type having a gain waveguide structure and a selective oxidization type having a refractive-index waveguide structure. Nowadays, the latter is getting the mainstream.

The selective oxidization type semiconductor laser is equipped with a laser portion of a mesa structure and oxidizes part of a multilayer reflection mirror located in the vicinity of the active layer so that the electric resistivity can be increased and the refractive index can be reduced, this resulting in an optical waveguide for current confinement. The strong light confinement effect reduces the threshold current and improves the responsibility.

In order to stabilize the lateral oscillation mode, which is an important characteristic item in practical use, in a zeroth-order fundamental mode, it is necessary to reduce the diameter or aperture of the non-oxidized region (which corresponds to the current path) in the current confinement region to, typically, 4 μm or smaller. However, the optical output available in that case is reduced to 1 milliwatt.

There is a proposal that copes with tradeoff problems of stabilization of the lateral mode and power up in the selective oxidization type surface emitting semiconductor laser. Such a proposal is described in, for example, Japanese Unexamined Patent Publication No. 2000-332355.

This publication proposes a surface emitting semiconductor laser having a new structure, which utilizes a phenomenon in which the strongest optical intensity in the fundamental lateral oscillation mode develops on the optical axis of the optical waveguide (which is close to the center of the current confinement portion of the mesa structure and is located in the direction perpendicular to the substrate) while high-order lateral oscillation develops in a position away from the optical axis. An opening or aperture is formed in an upper electrode formed on the upper multilayer reflection mirror. The refractive index of the multilayer reflection mirror that is in contact with the upper electrode is made smaller than that of the multilayer reflection mirror exposed via the aperture.

The diameter of the aperture in the upper electrode and the diameter of the current confinement portion (non-oxidized region) is determined depending on the degree of reduction in the refractive index of the multilayer reflection mirror. Reducing the refractive index of the resonator is intended to increase, in that position, the optical loss of the high-order lateral modes in which the strongest intensity is available and to thus suppress oscillation. This means that the lateral mode is brought into the fundamental mode by control using two parameters, namely, the diameter of the current confinement portion (non-oxidized region) and the diameter of the aperture in the upper electrode. It is to be noted that, conventionally, only the diameter of the current confinement portion is used to bring the lateral oscillation mode into the fundamental mode. The use of the two parameters contributes to suppressing the high-order lateral modes and increasing the fundamental lateral mode while minimizing the loss of the fundamental lateral mode.

The following document handles the above-mentioned problems: H. J. Unold et al., “Increased-area oxidized single-fundamental mode VCSEL with self-aligned shallow etched surface relief”, ELECTRONICS LETTERS 5^{th} August 1999, Vol. 35, No. 16. The document teaches a self-alignment technique in which a shallow groove is formed on the surface of a p-type DBR and a three-layer photoresist is used for improving the accuracy in alignment of the groove with the aperture of the non-oxidized region.

According to the teachings described in Japanese Unexamined Patent Publication No. 2000-332355, it is essential to put into position the aperture in the upper electrode on the upper multilayer reflection mirror and the central axis of the non-oxidized region (current path) of the current confinement portion. If the aperture in the upper electrode deviates from the central axis of the non-oxidized region in positioning, oscillation in the fundamental lateral mode to be picked up will be excessively suppressed. This may not suppress the high-order lateral modes sufficiently.

In order to avoid the above, there is no way other than that of improving the accuracy of positioning the photomask. Even when the photomask is finely adjusted while viewing a positioning mark positioned thereon, the accuracy of fine adjustment is only ±0.5 μm even by a skilled person. In practice, a deviation greater than the above accuracy takes place frequently.

The surface emitting semiconductor laser proposed by H. J. Unold et al. employs the three-layer self-alignment technique that needs the etching groove on the DBR surface. It is therefore difficult to form the etching groove reliably and accurately.

Consequently, the conventional surface emitting semiconductor laser has the characteristics that strongly depend on the process condition.

### SUMMARY OF THE INVENTION

The present invention has been made in view of the above circumstances and provides a surface emitting semiconductor laser and a method of fabricating the same.

More specifically, the present invention provides a surface emitting semiconductor laser capable of generating stabilized laser output in the fundamental lateral mode oscillation, and provides a method of fabricating the same.

According to an aspect of the present invention, a surface emitting semiconductor laser includes: a substrate; a lower semiconductor multilayer mirror of a first conduction type formed on the substrate; an upper semiconductor multilayer mirror of a second conduction type; an active region disposed between the lower and upper semiconductor multilayer mirrors; a current confinement portion arranged between the lower and upper semiconductor multilayer mirrors; and a metal layer provided on the upper semiconductor multilayer mirror, a mesa structure being formed so as to include at least the upper semiconductor multilayer mirror, the current confinement portion and the metal layer, the mesa structure having a side surface aligned with the metal layer.

According to another aspect of the present invention, a surface emitting semiconductor laser includes: a substrate; multiple semiconductor layers formed on the substrate, the multiple semiconductor layers including a first reflection mirror of a first conduction type, an active region on the first reflection mirror, at least one current confinement layer partially including an oxidized region, and a second reflection mirror of a second conduction type; and an electrode having a light emitting window formed on the multiple semiconductor layers, a mesa structure being formed so as to include at least the first reflection mirror, the current confinement layer and the electrode and extending at least from the second reflection mirror to the current confinement layer, the mesa structure having a shape that corresponds to a shape of the electrode.

According to yet another aspect of the present invention, a method of fabricating a surface emitting semiconductor laser includes the steps of: forming multiple semiconductor layers on a substrate, the multiple semiconductor layers including first and second semiconductor mirrors, a current confinement layer and an active layer; forming a metal layer on the multiple semiconductor layers; forming the metal layer into a predetermined shape; etching the multiple semiconductor layers with the metal layer being used as a mask so that a mesa structure extending at least from the second semiconductor mirror to the current confinement layer is formed; and exposing the mesa structure to a water vapor atmosphere so as to form an oxidized region that is part of the current confinement layer.

According to a further aspect of the present invention, a method of fabricating a surface emitting semiconductor laser includes the steps of: forming multiple semiconductor layers on a substrate, the multiple semiconductor layers including first and second semiconductor mirrors, a current confinement layer and an active layer; forming a metal layer on the multiple semiconductor layers; forming an insulating layer on the metal layer; patterning the insulating layer and the metal layer into a predetermined shape; anisotropically etching the multiple semiconductor layers with a patterned insulating layer and a patterned metal layer so that a mesa structure extending at least from the second semiconductor mirror to the current confinement layer is formed; and exposing the mesa structure to a water vapor atmosphere so as to form an oxidized region that is part of the current confinement layer.

### BRIEF DESCRIPTION OF THE DRAWINGS

Other objects, features and advantages of the present invention will become more apparent from the following detailed description when read in conjunction with the accompanying drawings, in which:

FIG. 1A is a cross-sectional view of a surface emitting semiconductor laser according to an embodiment of the present invention;

FIG. 1B is a plan view of the semiconductor laser shown in FIG. 1A; and

FIGS. 2A through 2K are cross-sectional views illustrating steps of a method of fabricating the semiconductor laser shown in FIGS. 1A and 1B.

### DESCRIPTION OF THE PREFERRED EMBODIMENTS

A description will now be given of embodiments of the present invention with reference to the accompanying drawings.

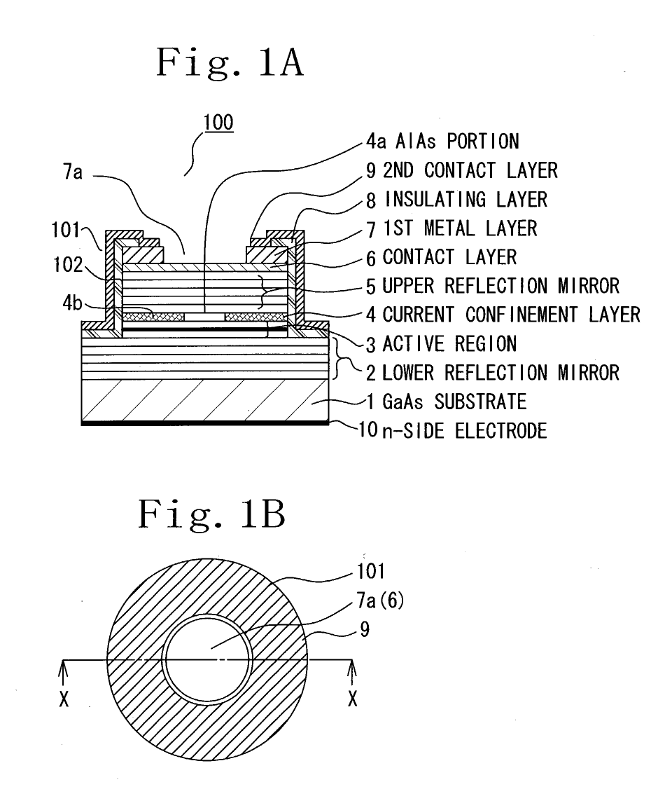

FIG. 1A is a cross-sectional view of a surface emitting semiconductor laser according to an embodiment of the present invention, and FIG. 1B is a plan view thereof. The cross-sectional view of FIG. 1A is taken along a line X-X shown in FIG. 1B. A surface emitting semiconductor laser 100 is of a selective oxidization type equipped with a laser portion 101 of a cylindrical mesa structure, which may be called a post structure or pillar structure. In FIG. 1A, a protection film with which the laser portion 101 and a bonding pad portion extending from a metal contact layer are not illustrated for the sake of simplicity.

The semiconductor laser has an n-type GaAs substrate 1, an n-type lower multilayer reflection mirror 2 provided on the substrate 1, and an active region 3 provided on the lower multilayer reflection mirror 2. The active region 3 is a laminate of an undoped spacer layer, an undoped quantum well layer and an undoped harrier layer. A current confinement portion 4 is formed on the active region 3. The current confinement portion 4 includes an AlAs portion 4a that defines a circular optical opening or aperture located in the center, and an AlAs oxide region 4b provided around the AlAs portion 4a. The AlAs oxide region 4b confines current and light, and also reduces the stray capacitance. A p-type upper multilayer reflection mirror 5 is provided on the current confinement portion. A p-type contact layer 6 is provided on the upper multilayer reflection mirror 5.

A first metal contact layer 7 (metal layer) having a ring shape is provided on the contact layer 6. The first metal contact layer 7 has a laser emitting window 7a, which has a circular shape. The center of the window 7a approximately coincides with the optical axis that is perpendicular to the substrate 1 and passes through the center of the mesa structure 101. The center of the AlAs portion 4a of the current confinement region 4 approximately coincides with the optical axis. That is, the AlAs portion 4a and the laser emitting window 7a are aligned. An interlayer insulating layer 8 is provided so as to cover the side and bottom surfaces of the mesa structure 101 and part of the upper surface of the first metal contact layer 7. A second metal contact layer 9, which serves as a p-side electrode, is isolated from the side surface of the mesa structure 101 and the side surface of the first metal contact layer 7 via the interlayer insulating layer 8. The second metal contact layer 9 is connected to the surface of the first metal contact layer 7 on the top surface of the meta structure 101. An n-side back surface electrode 10 is provided on the back surface of the substrate 1.

The lower multilayer reflection mirror 2 is made up of multiple pairs of an n-type Al_{0.9}Ga_{0.1}As layer and an n-type Al_{0.3}Ga_{0.7}As layer. Each layer is λ/4nᵣ thick where λ is the oscillation wavelength and nᵣ is the refractive index of the medium. The paired layers having different composition ratios are alternately laminated to a thickness of 40.5 periods. The carrier concentration of the lower multilayer reflection mirror 2 is 3×10¹⁸ cm⁻³ after silicon that is an n-type impurity is doped.

The upper multilayer reflection mirror 5 is made up of multiple pairs of a p-type Al_{0.9}Ga_{0.1}As layer and a p-type Al_{0.3}Ga_{0.7}As layer. Each layer is λ/4nᵣ thick where λ is the oscillation wavelength and nᵣ is the refractive index of the medium. The paired layers having different composition ratios are alternately laminated to a thickness of 30 periods. The carrier concentration of the lower multilayer reflection mirror 5 is 5×10¹⁸ cm⁻³ after carbon that is a p-type impurity is doped. A lowermost layer 5a of the upper multilayer reflection mirror 5 is made of AlAs rather than Al_{0.9}Ga_{0.1}As because the lowermost layer 5a is changed to the current confinement portion 4 by a later process.

In order to reduce the series resistance of the laser, practically, an intermediate (graded) layer may be interposed between the p-type Al_{0.9}Ga_{0.1}As layer and the p-type Al_{0.3}Ga_{0.7}As layer of the upper multilayer reflection mirror 5, the intermediate layer having an intermediate composition ratio between that of the p-type Al_{0.9}Ga_{0.1}As layer and that of the p-type Al_{0.3}Ga_{0.7}As layer. The above intermediate layer is not illustrated for the sake of simplicity.

The active region 3 has a quantum well structure in which a quantum well layer of an undoped Al_{0.11}Ga_{0.89}As quantum well layer having a thickness of 8 nm and a barrier layer of an undoped Al_{0.3}Ga_{0.7}As layer having a thickness of 5 nm are alternately laminated. The active region 3 is designed to have light emission at the 780 nm wavelength. A spacer layer formed by an undoped Al_{0.6}Ga_{0.4}As layer which is one of the layers forming the active region 3 includes a quantum well structure in the center thereof. The whole spacer layer has a film thickness as large as an integral multiple of λ/nᵣ where λ is the oscillation wavelength and nᵣ is the refractive index of the medium.

The contact layer 6 contacts an electrode via which current is supplied. The contact layer is a p-type GaAs layer, and is as thin as 20 nm, having a carrier concentration of 1×10²⁰ cm⁻³ after it is doped with zinc serving as the p-type impurity. The first metal contact layer 7 is a laminate of Au—Zn. Preferably, the refractive index of the portion of the contact layer 6 covered with the first metal contact layer 7 is made lower than that of the portion exposed via the laser emitting window 7a. The occurrence of the high-order lateral mode is suppressed by reducing the reflectance or reflectivity in a position away from the optical axis, so that laser light of the fundamental lateral mode can stably be emitted. The way of reducing the reflectance is disclosed in, for example, Japanese Unexamined Patent Publication No. 2000-332355.

In the surface emitting semiconductor laser 100, a side surface 102 of the mesa structure 101 (laser portion) is aligned with the outer shape of the first metal contact layer 7. The side surface of the mesa structure corresponds to the side surface of the mesa structure except the interlayer insulating layer 8. The alignment of the side surface of the mesa structure with the first metal contact layer 7 means that the side surfaces of the active region 3, current confinement portion 4, upper multilayer reflection mirror 5, contact layer 6 and the first contact layer 7 included in the mesa structure are all aligned. When the mesa structure is subject to selective oxidization, the current confinement portion 4 is oxidized from the side surface thereof so that the oxide region 4b is formed, while the remaining non-oxidized region, namely, the aperture of the AlAs portion 4a is aligned with the laser emitting window 7a. Thus, the center of the aperture of the AlAs portion 4a and the center of the window 7a approximately coincide with the center (optical axis) of the mesa structure.

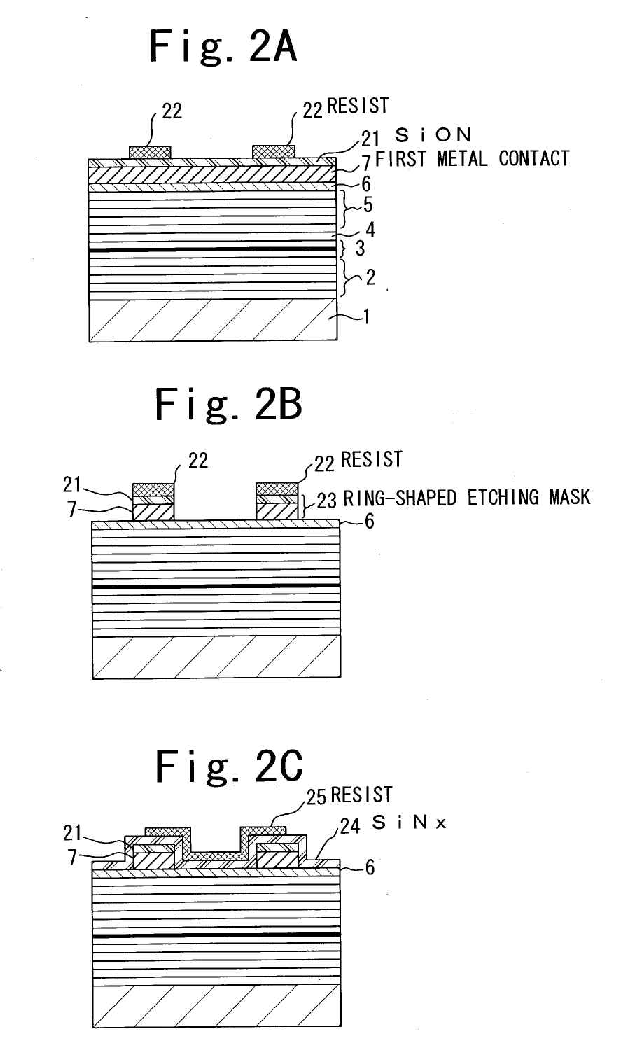

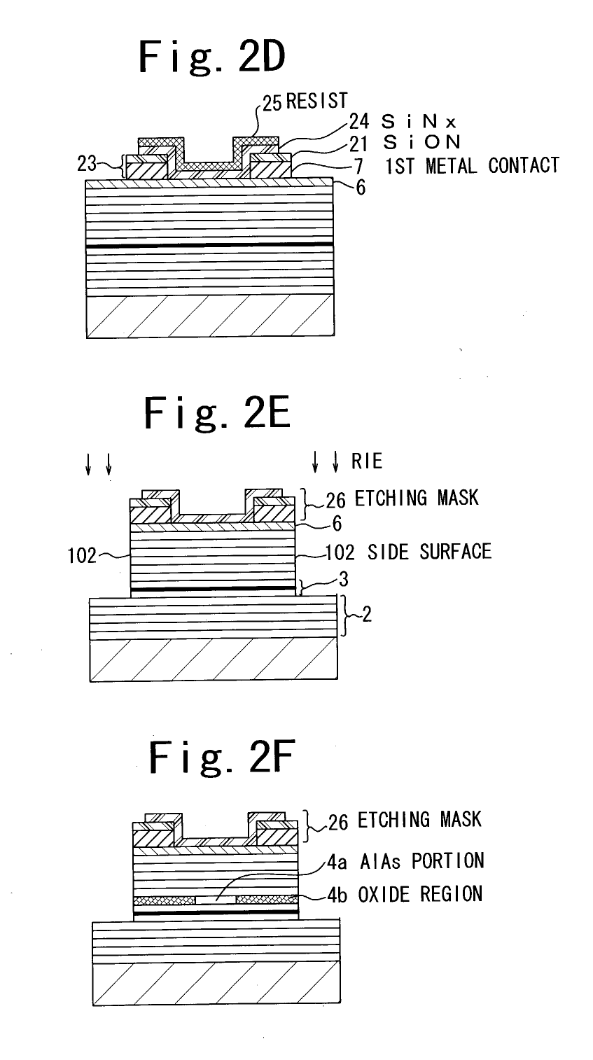

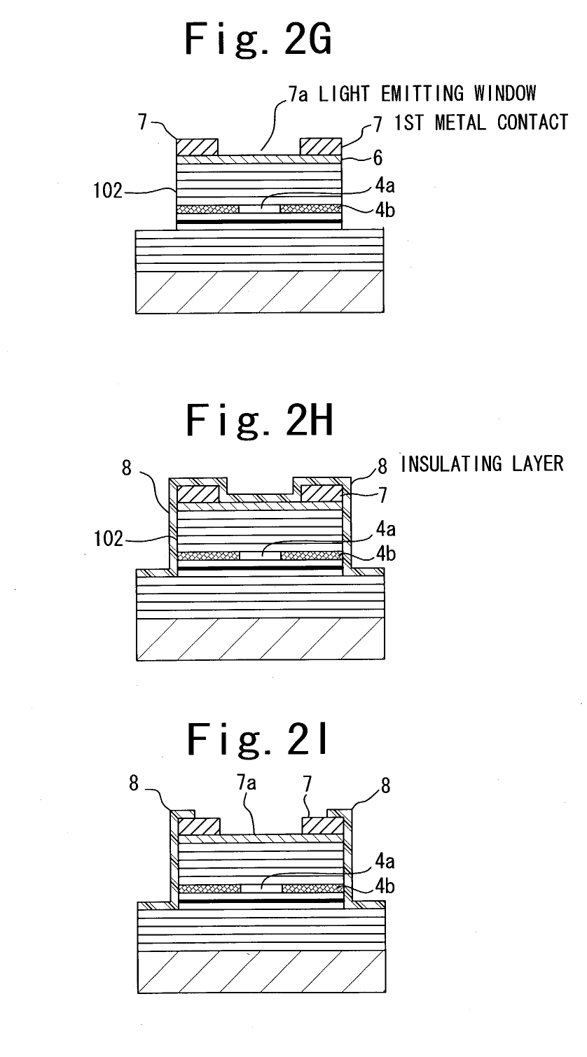

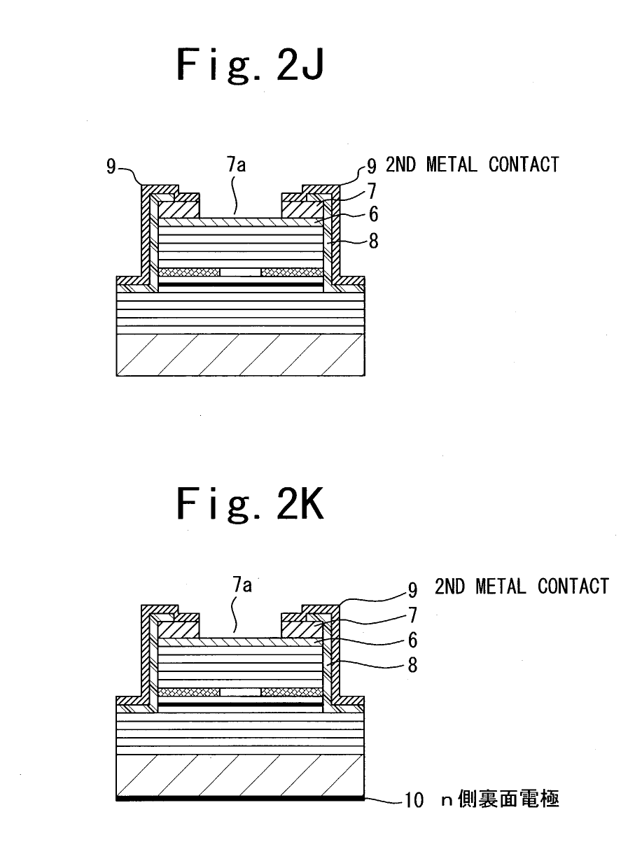

A description will now be given of a method of fabricating the above-mentioned surface emitting semiconductor laser according to the present embodiment. A wafer is removed from a growth chamber, the wafer being composed of the lower multilayer reflection mirror 2, the active region 3, the current confinement portion 4, the upper multilayer reflection mirror 5 and the contact layer 6 laminated on the semiconductor substrate 1 in this order. As shown in FIG. 2A, the entire wafer surface is coated with the fist metal contact layer 7 made of Au—Zn and a SiON layer 21 provided thereon. Subsequently, a photoresist 22 having an inside diameter of 5-10 μm and an outside diameter of 20-30 μm is formed by the photolithography technology.

By using the resist 22 as a mask, the SiON layer 21 and the Au—Zn layer 7 are etched in this order, so that the central and circumferential portions of the contact layer can be exposed as shown in FIG. 2B. Removal of the photoresist 22 results in a ring-shaped etching mask 23 made up of the patterned Au—Zn contact layer 7 and the patterned SiON layer 21 (first masking material).

Next, a SiNₓ layer 24 serving as a second masking material is deposited by RF sputtering. Then, as shown in FIG. 2C, a circular photoresist 25 is formed which is 1-2 μm smaller than the outside diameter of the ring-shaped etching mask composed of the Au—Zn layer 7 and the SiON layer 21 and is sufficiently larger than the inside diameter thereof. Using the photoresist 25 thus formed, the SiNₓ layer 24 is etched, as shown in FIG. 2D. In this etching, the underlying SiON layer 21 may be partially etched. However, no problem occurs as long as the SiON layer 21 is not completely removed. Preferably, etching that is selective between SiNₓ and SiON and is capable of effectively removing SiNₓ is used. By removing the photoresist 25, an etching mask 26 becomes available which has the ring-shaped etching mask 23, and the SiNₓ layer (second masking material 24) overlaps thereon. The etching mask 23 is composed of the patterned laminate of the Au—Zn layer 7 and the SiON layer 21.

The laminate is subject to anisotropic etching with the etching mask 26 by reactive ion etching (RIE). As shown in FIG. 2E, the p-type GaAs contact layer 6, the upper multilayer reflection mirror 5, the current confinement portion 3 and the active region 3 are removed so as to form a post-shaped construction. The upper multilayer reflection mirror 5 is a laminate of pairs each having the p-type Al_{0.9}Ga_{0.1}As layer and n-type Al_{0.3}Ga_{0.7}As layer. Etching may be performed so that part of the lower multilayer reflection mirror 2 is etched.

The mesa structure formed by etching mentioned above has a shape that corresponds to that of the etching mask 26. More specifically, the side surface 102 of the mesa structure is flush with the outer shape or side surface of the ring-shaped etching mask 23. The contact layer 6 exposed via the aperture in the contact layer 7 is protected by the second masking material 24.

Thereafter, the wafer is put in a water vapor atmosphere at 350° C. for approximately 20 minutes. This is so-called wet oxidizing. The AlAs layer in the upper multilayer reflection mirror 5 is partially oxidized from the outer circumference thereof. The oxidized portion of the AlAs layer becomes the high-resistance region 4b, which serves as the current confinement portion 4 in which the aperture of the AlAs portion 4a is formed in the center thereof, as shown in FIG. 2F.

The diameter of the aperture of the AlAs portion 4a surrounded by the AlAs oxide (high-resistance region) is important to enhance the optical output at the time of the fundamental lateral mode oscillation, and is required to be carefully selected taking the light emitting window 7a in the first ring-shaped metal contact layer of Au—Zn into consideration.

The experiments conducted by the inventors and an estimation of loss between the oscillation modes show that the optical output of the fundamental lateral oscillation mode oscillation is maximized when the diameter of the light emitting window 7a in the first metal contact layer 7 is equal to the diameter of the aperture of the AlAs portion 4a in the current confinement portion 4 or is greater than about 1 μm.

However, it is important to realize the axial alignment between the window 7a and the aperture of the AlAs portion 4a. The fabrication process according to the present invention using the self-alignment process easily enables the axial alignment, and has the following steps.

The first step utilizes the high accuracy of positioning by the photolithography technique, and determines the inside and outside diameters of the first metal contact layer 7 of the ring shape at the stage of photolithography.

The second step protects a portion corresponding to the outside diameter of the first metal contact layer 7 by the SiON layer 21, which is the first masking material.

The third step protects the portion that corresponds to the inside diameter of the first metal contact layer 7 by the SiNₓ layer 24 that is the second masking material. Then, the wafer is etched so as to expose AlAs layer 4 located in the lowermost layer of the upper multilayer reflection mirror 5. Then, the wafer is annealed to form the current confinement portion 4.

The aperture of the current confinement portion 4 is defined so that the outside diameter of the first metal contact layer 7 that is defined with the accuracy of photolithography is used as the base point. Thus, the axes of the window 7a and the aperture of the AlAs portion 4a are aligned with high positioning accuracy.

Referring to FIG. 2G, the SiON layer 21 and the SiNₓ layer 24 used as the etching mask are removed. The circumferential portion on the top of the mesa structure is covered by the first metal contact layer 7 made of Au—Zn, and the contact layer 6 is exposed via the light emitting window 7a located in the center of the top.

As shown in FIG. 2H, the whole surface of the wafer (substrate) except the back and side surfaces is coated with SiO₂. This covers at least the side and bottom surfaces of the post with the interlayer insulating layer 8 of SiO₂.

The interlayer insulating 8 is removed by etching so that part of the surface of the first metal contact layer 7 and the light emitting window 7a are exposed, as shown in FIG. 2I. Then, Ti/Au is deposited so as to contact the first metal contact layer 7 of Au—Zn, and is patterned so as to define the second metal contact layer 9, as shown in FIG. 2J. The second metal contact layer 9 serves as the p-side electrode.

Thereafter, a metal of Au/Ge/Ni/Au is deposited on the back surface of the GaAs substrate 1 so that the n-side backside electrode 10 can be formed, as shown in FIG. 2K. Then, the substrate is annealed in a forming gas of nitrogen and hydrogen at approximately 300° C. for five minutes. This makes an alloy of the first metal contact layer 7 and the contact layer 6, so that the high-power surface emitting semiconductor layer of the 780 nm wavelength as shown in FIGS. 1A and 1B can be produced. The portion of the contact layer 6 that makes an alloy with the first metal contact layer 7 has a lower reflectance than that of the exposed portion thereof.

In the above-mentioned embodiment of the present invention, the circular aperture in the first metal contact layer 7 and the aperture in the current confinement portion 4 have circular shapes. Besides, it is possible to employ any shape capable of defining the center or axis of rotational symmetry, such as a square, rectangle, oval, ellipse, or rhomboid. Even in such an alternative, the same advantages can be provided. When a plane shape having such a symmetry that 180° rotation returns to the original state) such as a rectangle, oval or ellipse, it is additionally possible to control the polarization plane of emitting light.

In the foregoing, the contact layer 6 is made of GaAs. However, the contact layer 6 is not limited to GaAs but may be made of, for example, GaInP. As is known, GaInP has an energy band gap of approximately 1.9 eV and is transparent to light of 780 nm wavelength emitted from the active layer. The GaInP contact layer has less absorption of light than the GaAs contact layer and is more efficient. It is possible to employ any material that has a lattice constant close to that of the semiconductor substrate, typically, a lattice mismatch ratio of 0.1% or lower and allows light emitted from the active layer to pass therethrough.

In the foregoing, the upper multilayer reflection mirror 5 is of p type, and the lower multilayer reflection mirror 2 is of n type. Alternatively, the mirror 5 may be of n type and the mirror 2 may be of p type. Generally, there is a worry that the p-type layer has large resistance due to band discontinuity (forbidden band) and large absorption of light by free carriers (free electrons), as compared to the n-type layer. Therefore, an increased number of layers that form the p-type upper multilayer reflection mirror 5 may degrade the laser characteristics. From the above viewpoints, it is preferable to have a smaller number of layers of the p-type multilayer reflection mirror 5 than that of layers of the n-type multilayer reflection mirror 2.

Light can be emitted from the backside of the substrate 1 by using a larger number of layers of the upper multilayer reflection mirror 5 than that of layers of the lower multilayer reflection mirror 2 so that the upper reflection mirror 5 has a higher reflectance than the lower reflection mirror 2. From another viewpoint, the resistance of the laser portion is inversely proportional to the area. Therefore, the upper multilayer reflection mirror 5 shaped into a post may serve as a factor that increases the resistance of the laser portion. It follows that for the same area, it is preferable to shape the n-type upper multilayer reflection mirror into a post.

The quantum well active layer 3 is not limited to GaAs/AlGaAs semiconductor mentioned before, but may be made of GaAs/InGaAs semiconductor or GaAs/GaInNAs semiconductor. The wavelength of light emitted from these quantum well is transparent to the GaAs substrate, this enabling light to be emitted via the backside of the substrate and providing an advantage in the fabrication process.

In the foregoing, MOCVD is used for crystal growth. Alternatively, molecular beam epitaxy (MBE) may be used for crystal growth.

In the foregoing, the AlGaAs (including the AlAs layer) is oxidized while heating it at a temperature of 350° C. However, the oxidization process is not limited to the above but any method controllable to define the desired size of the current path may be employed. As the temperature is increased, the oxidization rate is raised, so that the oxidized region can be formed in a shorter period of time.

The present invention is not limited to the specifically described embodiments, but includes other embodiments, variations and modifications In the foregoing, the contact layer 6 and the upper multiplayer reflection mirrors are handled as being functionally separate from each other. However, the contact layer 6 may form part of the upper multilayer reflection mirror 5.

According to the present invention, the mesa structure is aligned with the metal portion of the upper multilayer reflection mirror 5 in the selectively oxidized surface emitting laser. This improves the accuracy of positioning of the individual parts of the laser portion and suppresses the high-order lateral mode oscillation while minimizing loss in the fundamental lateral mode oscillation. This laser structure can be realized by the self-aligned process, so that a surface emitting semiconductor layer having a stabilized lateral mode, a low threshold current and improved reliability can be fabricated.

Finally, the present invention is summarized below from various aspects. The reference numerals given below are used to merely facilitate the understanding of the invention, and the following structural elements are not limited to those given the reference numerals.

According to an aspect of the invention, the surface emitting semiconductor laser includes: a substrate (1); a lower semiconductor multilayer mirror (2) of a first conduction type formed on the substrate; an upper semiconductor multilayer mirror (5) of a second conduction type; an active region (3) disposed between the lower and upper semiconductor multilayer mirrors; a current confinement portion (4) arranged between the lower and upper semiconductor multilayer mirrors; and a metal layer (7) provided on the upper semiconductor multilayer mirror, a mesa structure being formed so as to include at least the upper semiconductor multilayer mirror, the current confinement portion and the metal layer, the mesa structure having a side surface aligned with the metal layer. It is therefore possible to accurately align at least the upper semiconductor multilayer (5) and the side surface of the current confinement portion (4) contained in the mesa structure of the laser portion with the metal layer. Thus, the accuracy of positioning the structural parts of the laser portion, particularly the metal layer and the current confinement portion can be improved, this stabilizing emission of laser light.

The surface emitting semiconductor laser may be configured so that the side surface of the mesa structure is aligned with a surface that defines an outer shape of the metal layer. Preferably, the side surface of the mesa structure is aligned with the outer shape of the metal layer. The metal layer may have a circular or rectangular outer shape. By forming the mesa structure having the same shape as the outer shape of the metal layer, it is possible to accurately define the current path (for example, the position of the selectively oxidized region) with the outer shape of the metal (electrode) layer being as the base point. Preferably, the side surface of the mesa structure is formed by etching with the metal layer being used as a mask. That is, the use of the metal layer as a mask enables self-alignment of the mesa structure matched with the shape of the metal layer.

Preferably, the metal layer has a window from which laser light is emitted, and a reflectance of the upper semiconductor multilayer mirror covered by the metal layer is lower than that of the upper semiconductor multilayer mirror exposed via the window. Preferably, the window is provided concentrically with the center of the laser portion, and the center of the window approximately coincides with the optical axis of the laser portion. By setting the reflectance of the upper semiconductor layer (part of the upper semiconductor multilayer mirror) covered with the metal layer lower than that of the center portion thereof, it is possible to suppress laser light in high-order lateral modes having high intensity in a position away from the optical axis of the laser portion and to stabilize laser light in the fundamental lateral mode emitted via the window and reduce the threshold current for emitting.

Preferably, the metal layer is connected to a second metal contact layer (9), and current supplied from the second metal contact layer is supplied to the upper semiconductor multilayer mirror via the metal layer. The metal layer (7) serves as a contact (electrode) for supplying current to the laser portion in addition to the function of emitting laser.

Preferably, the mesa structure includes an insulating layer (8) provided on the side surface of the mesa structure; the second metal contact layer is provided on the insulating layer; and the second metal contact layer is isolated from the side surface of the mesa structure by the insulating layer. The second metal contact layer includes a conductor path extending to a metal bonding pad via which driving current may be applied to the metal layer.

Preferably, the current confinement portion includes an oxidized region defined by selectively oxidizing the mesa structure from the side surface thereof and a non-oxidized region surrounded by the oxidized region; and an aperture defined by the non-oxidized region is substantially aligned with the window. The current confinement portion includes, for example, an AlAs layer. The mesa structure is subject to a water vapor atmosphere so that the AlAs layer is selectively oxidized from the sidewall thereof. This results in the oxidized region (Al₂O₃) and the non-oxidized region (AlAs) The mesa structure has the side surface aligned with the shape of the electrode. Thus, the oxidized region (or the aperture of the non-oxidized region) is aligned with the electrode. Thus, the window formed by the electrode and the aperture of the self-aligned non-oxidized region do not have alignment error caused when the mask is used. This stabilizes laser oscillation in the fundamental lateral mode. Further, it is possible to prevent misalignment in the fabrication process and easily produce the reliable surface emitting semiconductor laser devices.

The window in the metal layer may be larger than an aperture (4a) defined by the non-oxidized region. For instance, if the metal layer is 1 μm greater than the aperture, a relatively high laser output can be obtained.

The metal layer may be a metal containing at least one of Au, Pt, Ti, Ge, Zn, Ni, In, W and ITO (Indium Tin Oxide). Thus, it is possible to appropriately reduce the reflectance of the upper semiconductor layer serving as the upper multilayer mirror that contacts the metal layer. More preferably, an alloy of the metal layer and the semiconductor layer may be made.

The upper semiconductor multilayer mirror may a contact layer (6), and the metal layer may be formed on the contact layer. The contact layer may be provided on the upper semiconductor multilayer mirror. In any case, the contact layer functions as the semiconductor mirror or makes a contact. The metal layer is provided on the contact layer.

According to another aspect of the present invention, the surface emitting semiconductor laser includes: a substrate (1); multiple semiconductor layers formed on the substrate, the multiple semiconductor layers including a first reflection mirror (2) of a first conduction type, an active region (3) on the first reflection mirror, at least one current confinement layer (4) partially including an oxidized region, and a second reflection mirror (5) of a second conduction type; and an electrode (6-9) having a light emitting window (4a) formed on the multiple semiconductor layers, a mesa structure being formed so as to include at least the first reflection mirror, the current confinement layer and the electrode and extending at least from the second reflection mirror to the current confinement layer, the mesa structure having a shape that corresponds to a shape of the electrode. The mesa structure has a shape that matches the shape of the electrode having the window. Thus, the oxidized region in the current confinement layer included in the mesa structure is self-aligned with the light emitting window. This prevents alignment error and generates stable laser light of the fundamental lateral mode with high power.

Preferably, the multiple semiconductor layers have a contact region (6) having a comparatively high impurity concentration on the second reflection mirror, and the electrode is electrically connected to the contact layer. This reduces the series resistance and reduces the threshold current for laser oscillation.

Preferably, the electrode may be connected to the contact layer with an ohmic contact. In this case, it is possible to make an alloy by annealing at about 300° C. to 400° C.

The mesa structure is self-aligned by etching the multiple semiconductor layers with the electrode being used as a mask. Thus, the oxidized region (the aperture of the non-oxidized region) is self-aligned with the light emitting window of the electrode, this avoiding self-alignment error.

Preferably, the mesa structure has a cylindrical post structure. In this case, the electrode has at least a circular outer shape or side surface, and the mesa structure has a similar shape. A rectangular shape of the electrode may be used to define the mesa structure.

According to another aspect of the present invention, the method of fabricating a surface emitting semiconductor laser includes the steps of: forming multiple semiconductor layers on a substrate (1), the multiple semiconductor layers including first and second semiconductor mirrors (2, 5), a current confinement layer (4) and an active layer (3); forming a metal layer (7) on the multiple semiconductor layers; forming the metal layer into a predetermined shape; etching the multiple semiconductor layers with the metal layer being used as a mask so that a mesa structure extending at least from the second semiconductor mirror to the current confinement layer is formed; and exposing the mesa structure to a water vapor atmosphere so as to form an oxidized region (4a) that is part of the current confinement layer.

According to the above-mentioned method, the multiple semiconductor layers are etched with the patterned metal layer being used as mask, and the current confinement layer in the mesa structure is partially oxidized. The oxidized region (or the non-oxidized region) in the current confinement layer can be aligned with the patterned metal layer. That is, the metal layer and the current confinement layer, which layers play an important role for current confinement, can be accurately positioned so that laser light of the fundamental lateral mode can be stabilized with high power.

According to a further aspect of the invention, the method of fabricating a surface emitting semiconductor laser includes the steps of: forming multiple semiconductor layers on a substrate (1), the multiple semiconductor layers including first and second semiconductor mirrors (2, 5), a current confinement layer (4) and an active layer (3); forming a metal layer on the multiple semiconductor layers; forming an insulating layer (8) on the metal layer; patterning the insulating layer and the metal layer into a predetermined shape; anisotropically etching the multiple semiconductor layers with a patterned insulating layer and a patterned metal layer so that a mesa structure extending at least from the second semiconductor mirror to the current confinement layer is formed; and exposing the mesa structure to a water vapor atmosphere so as to form an oxidized region (4a) that is part of the current confinement layer. The metal layer is protected by the insulating layer and is not damaged during etching. The method is effective to a case where the metal layer is used as an electrode.

Preferably, the method includes the steps of: removing the insulating layer from the metal layer; and forming a second metal layer on the metal layer. The insulating layer protects the surface of the metal layer from contamination such as etchant at the time of forming the mesa structure. Then, the insulating layer is removed.

Preferably, the metal layer and the insulating layer are patterned into a ring shape, and there is further provided the step of forming a second patterned insulating layer on a ring-shaped pattern, the second patterned insulating layer covering an upper surface of the multiple semiconductor layers exposed via the ring-shaped pattern. It is thus possible to suppress high-order lateral mode oscillation having a comparative strong intensity in a position away from the center of the mesa structure and to emit laser light of the fundamental lateral mode. In addition, the size of the oxidized region in the current confinement layer is aligned with the window of the metal layer, so that stable laser output can be generated.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A surface emitting semiconductor laser comprising:
a substrate;
a lower semiconductor multilayer mirror of a first conduction type formed on the substrate;
an upper semiconductor multilayer mirror of a second conduction type;
an active region disposed between the lower and upper semiconductor multilayer mirrors;
a current confinement portion arranged between the lower and upper semiconductor multilayer mirrors; and
a metal layer provided on the upper semiconductor multilayer mirror,
a mesa structure being formed so as to include at least the upper semiconductor multilayer mirror, the current confinement portion and the metal layer,
the mesa structure having a side surface aligned with the metal layer.

2. The surface emitting semiconductor laser as claimed in claim 1, wherein the side surface of the mesa structure is aligned with a surface that defines an outer shape of the metal layer.

3. The surface emitting semiconductor laser as claimed in claim 1, wherein the side surface of the mesa structure is formed by etching with the metal layer being used as a mask.

4. The surface emitting semiconductor laser as claimed in claim 1, wherein:
the metal layer has a window from which laser light is emitted; and
a reflectance of the upper semiconductor multilayer mirror covered by the metal layer is lower than that of the upper semiconductor multilayer mirror exposed via the window.

5. The surface emitting semiconductor laser as claimed in claim 1, wherein:
the metal layer is connected to a second metal contact layer; and
current supplied from the second metal contact layer is supplied to the upper semiconductor multilayer mirror via the metal layer.

6. The surface emitting semiconductor laser as claimed in claim 5, wherein:
the mesa structure includes an insulating layer provided on the side surface;
the second metal contact layer is provided on the insulating layer; and
the second metal contact layer is isolated from the side surface of the mesa structure by the insulating layer.

7. The surface emitting semiconductor laser according to claim 4, wherein:
the current confinement portion includes an oxidized region defined by selectively oxidizing the mesa structure from the side surface thereof, and a non-oxidized region surrounded by the oxidized region; and
an aperture defined by the non-oxidized region is substantially aligned with the window.

8. The surface emitting semiconductor laser according to claim 7, wherein the window in the metal layer is larger than an aperture defined by the non-oxidized region.

9. The surface emitting semiconductor laser according to claim 1, wherein the metal layer comprises a metal containing at least one of Au, Pt, Ti, Ge, Zn, Ni, In, W and ITO.

10. The surface emitting semiconductor laser according to claim 1, wherein the upper semiconductor multilayer mirror comprises a contact layer, and the metal layer is formed on the contact layer.

11. A surface emitting semiconductor laser comprising:
a substrate;
multiple semiconductor layers formed on the substrate, the multiple semiconductor layers including a first reflection mirror of a first conduction type, an active region on the first reflection mirror, at least one current confinement layer partially including an oxidized region, and a second reflection mirror of a second conduction type; and
an electrode having a light emitting window formed on the multiple semiconductor layers,
a mesa structure being formed so as to include at least the first reflection mirror, the at least one current confinement layer and the electrode and extending at least from the second reflection mirror to the current confinement layer,
the mesa structure having a shape that corresponds to a shape of the electrode.

12. The surface emitting semiconductor laser as claimed in claim 11, wherein:
the multiple semiconductor layers include a contact region having a comparatively high impurity concentration on the second reflection mirror; and
the electrode is electrically connected to the contact layer.

13. The surface emitting semiconductor laser as claimed in claim 12, wherein the electrode is connected to the contact layer with an ohmic contact.

14. The surface emitting semiconductor laser as claimed in claim 11, wherein the mesa structure is self-aligned by etching the multiple semiconductor layers with the electrode being used as a mask.

15. The surface emitting semiconductor laser as claimed in claim 11, wherein the mesa structure has a cylindrical post structure.

16. A method of fabricating a surface emitting semiconductor laser comprising the steps of:
forming multiple semiconductor layers on a substrate, the multiple semiconductor layers including first and second semiconductor mirrors, a current confinement layer and an active layer;
forming a metal layer on the multiple semiconductor layers;
forming the metal layer into a predetermined shape;
etching the multiple semiconductor layers with the metal layer being used as a mask so that a mesa structure extending at least from the second semiconductor mirror to the current confinement layer is formed; and
exposing the mesa structure to a water vapor atmosphere so as to form an oxidized region that is part of the current confinement layer.

17. The method as claimed in claim 16, wherein the multiple semiconductor layers include a contact layer on the second semiconductor mirror, and the metal layer is formed on the contact layer.

18. The method as claimed in claim 17, wherein the metal layer comprises a metal containing at least one of Au, Pt, Ti, Ge, Zn, Ni, In, W and ITO.

19. A method of fabricating a surface emitting semiconductor laser comprising the steps of:
forming multiple semiconductor layers on a substrate, the multiple semiconductor layers including first and second semiconductor mirrors, a current confinement layer and an active layer;
forming a metal layer on the multiple semiconductor layers;
forming an insulating layer on the metal layer;
patterning the insulating layer and the metal layer into a predetermined shape;
anisotropically etching the multiple semiconductor layers with a patterned insulating layer and a patterned metal layer so that a mesa structure extending at least from the second semiconductor mirror to the current confinement layer is formed; and
exposing the mesa structure to a water vapor atmosphere so as to form an oxidized region that is part of the current confinement layer.

20. The method as claimed in claim 19, further comprising the steps of:
removing the insulating layer from the metal layer; and
forming a second metal layer on the metal layer.

21. The method as claimed in claim 19, wherein:
the step of patterning patterns the metal layer and the insulating layer into a ring shape; and
the method further comprises a step of forming a second patterned insulating layer on a ring-shaped pattern, the second patterned insulating layer covering an upper surface of the multiple semiconductor layers exposed via the ring-shaped pattern.
